(19) United States
(12) Patent Application Publication
(10) Pub. No.: US 2025/0324731 A1
(43) Pub. Date: Oct. 16, 2025

(54) INTEGRATED CIRCUIT DEVICES INCLUDING A BACKSIDE POWER DISTRIBUTION NETWORK STRUCTURE AND METHODS OF FORMING THE SAME

(71) Applicant: Samsung Electronics Co., Ltd., Suwon-si (KR)

(72) Inventors: Byounghoon Kim, Rexford, NY (US); Jongjin Lee, Clifton Park, NY (US); Wonkeun Chung, Clifton Park, NY (US); Joongsuk Oh, Watervliet, NY (US); Kang-ill Seo, Springfield, VA (US)

(21) Appl. No.: 18/956,476

(22) Filed: Nov. 22, 2024

Related U.S. Application Data
(60) Provisional application No. 63/632,047, filed on Apr. 10, 2024.

(51) Int. Cl. H01L 21/8238; H01L 27/092; H01L 29/06; H01L 29/08; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 62/151; H10D 84/0167; H10D 84/0186; H10D 84/85

(57) ABSTRACT

A method of forming an IC device includes: forming a sacrificial element in an epitaxial layer, the sacrificial element including a first portion and a second portion contacting the first portion; forming a transistor including a channel structure and a source/drain region on an upper surface of the epitaxial layer, wherein a portion of the epitaxial layer is between an upper surface of the second portion of the sacrificial element and the source/drain region; removing at least a portion of the epitaxial layer extending around the sacrificial element to expose a lower surface and sidewalls of the sacrificial element; forming an interlayer insulating layer surrounding the sacrificial element; replacing the sacrificial element with a power contact, the source/drain region contacting an upper surface of the power contact; and forming a power rail on a lower surface of the interlayer insulating layer that contacts a lower surface of the power contact.

### CROSS-REFERENCE TO RELATED APPLICATION(S)

The present application claims priority under 35 U.S.C. § 119 to U.S. Provisional Application Ser. No. 63/632,047 entitled “INTEGRATED CIRCUIT DEVICES INCLUDING NON-SELF-ALIGNED SUBSTRATE ISOLATION (SASI) SCHEME BACKSIDE POWER DISTRIBUTION NETWORK STRUCTURE AND METHODS OF FORMING THE SAME,” filed in the U.S. Patent and Trademark Office (USPTO) on Apr. 10, 2024, the disclosure of which is hereby incorporated by reference herein in its entirety.

### BACKGROUND

The present disclosure generally relates to integrated circuit devices and, more particularly, to integrated circuit devices including a backside power distribution network (BSPDN) structure.

Various structures, including a BSPDN, have been proposed to increase the integration density of integrated circuit (IC) devices (e.g., semiconductor devices). Backside power delivery refers to a technique of routing power supply lines on the backside of a semiconductor chip or IC device rather than the traditional frontside. BSPDN is a well-known approach for increasing logic density, improving power delivery (e.g., by reducing current-resistance (IR) drop) and performance, and facilitating standard cell height scaling.

An IC device including a BSPDN structure and a nano-sheet may include a self-aligned substrate isolation (SASI) layer (e.g., a bottom dielectric isolation (BDI) between the substrate and a nano-sheet) to protect the nano-sheet and increase the process margin of a placeholder (e.g., a sacrificial placeholder) for a backside contact (BSCA), such as a backside power contact. However, due at least in part to limited critical process parameters (CPPs), it may not be possible to fabricate an IC device including an SASI layer in some instances.

### SUMMARY

The present invention, as manifested in embodiments thereof, is directed to an IC device including a power contact (e.g., backside contact) that may be formed by replacing a preformed placeholder in a substrate, and methods of fabricating the same. According to methods described herein, the preformed placeholder may be formed before performing processing (e.g., front-side device processes) of elements (e.g., a nano-sheet) on a front-side of a device, and the placeholder may be replaced with a conductor (e.g., BSCA) after performing the front-side device processes. The preformed placeholder is formed without an SASI layer (i.e., non-SASI scheme). Accordingly, complexity and difficulties associated with the preformed placeholder during front-side device processing may be avoided.

According to an embodiment of the present disclosure, an integrated circuit device includes: an epitaxial layer; a channel structure; a source/drain region on an upper surface of the epitaxial layer and contacting the channel structure in a first direction parallel to the upper surface of the epitaxial layer; a backside contact electrically connected to the source/drain region; and a back-end-of-line (BEOL) structure on a lower surface of the epitaxial layer, opposite the upper surface of the epitaxial layer, the BEOL structure contacting the backside contact. The backside contact includes a first portion and a second portion on the first portion and contacting the source/drain region, a width of the first portion in the first direction being greater than a width of the second portion in the first direction.

In some embodiments, the integrated circuit device is configured such that the first portion of the sacrificial element is shaped as an inverted trapezoid and the second portion of the sacrificial element is rectangular in shape, and an upper surface of the first portion contacting the second portion is configured having a width in a first direction parallel to the upper surface of the epitaxial layer that is greater than a width of the second portion in the first direction. In one or more embodiments, the nano-sheet stack is formed directly on the epitaxial layer.

According to another embodiment of the present disclosure, a method of forming an integrated circuit device includes: forming a sacrificial element in an epitaxial layer, the sacrificial element including a first portion and a second portion contacting the first portion; forming a transistor including a channel structure and a source/drain region on an upper surface of the epitaxial layer, wherein a portion of the epitaxial layer is between an upper surface of the second portion of the sacrificial element and the source/drain region; removing at least a portion of the epitaxial layer extending around the sacrificial element to expose a lower surface and sidewalls of the sacrificial element; forming an interlayer insulating layer surrounding the sacrificial element; replacing the sacrificial element with a power contact, the source/drain region contacting an upper surface of the power contact; and forming a power rail on a lower surface of the interlayer insulating layer that contacts a lower surface of the power contact.

In some embodiments, the first portion of the sacrificial element is shaped as an inverted trapezoid and the second portion of the sacrificial element is rectangular in shape, and an upper surface of the first portion contacting the second portion is configured having a width in a first direction parallel to the upper surface of the epitaxial layer that is greater than a width of the second portion in the first direction. In one or more embodiments, the nano-sheet stack is formed directly on the epitaxial layer.

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1 is a schematic cross-sectional view of a first integrated circuit device comprising a plurality of nano-sheet stacks, according to some embodiments;

FIG. 2 is a schematic cross-sectional view conceptually depicting effects of placeholder height variation on a source/drain region in forming a metal-oxide-semiconductor (MOS) device comprising a nano-sheet stack;

FIGS. 3A and 3B are schematic cross-sectional views conceptually depicting damage to the source/drain region of the illustrative MOS device shown in FIG. 2 that may occur when an overgrowth process margin or an undergrowth process margin, respectively, of a preformed placeholder in the MOS device is exceeded; and

FIGS. 4A-4D are schematic cross-sectional views depicting intermediate processes in an example method of fabricating a semiconductor device, according to one or more embodiments of the present inventive concept.

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present invention, as manifested in the embodiments disclosed herein, are described in the context of integrated circuit (IC) devices including a power contact (e.g., backside contact (BSCA)) that may be formed by replacing a preformed placeholder (i.e., a sacrificial element) in a substrate. The preformed placeholder may be formed before performing a front-end-of-line (FEOL) portion of device fabrication, and thus the power contact may be formed without increasing the complexity of middle-end-of-line (MEOL) and/or back-end-of-line (BEOL) portions of the device fabrication. After the power contact is formed, a BSPDN structure may be formed on the power contact. The BSPDN structure may simplify the MEOL portion and/or the BEOL portion of the device fabrication. It is to be appreciated, however, that the invention is not limited to the specific devices and/or methods illustratively shown and described herein. Rather, it will become apparent to those skilled in the art given the teachings herein that numerous modifications to the embodiments shown are contemplated and are within the scope of the present inventive concept. That is, no limitations with respect to the embodiments shown and described herein are intended or should be inferred.

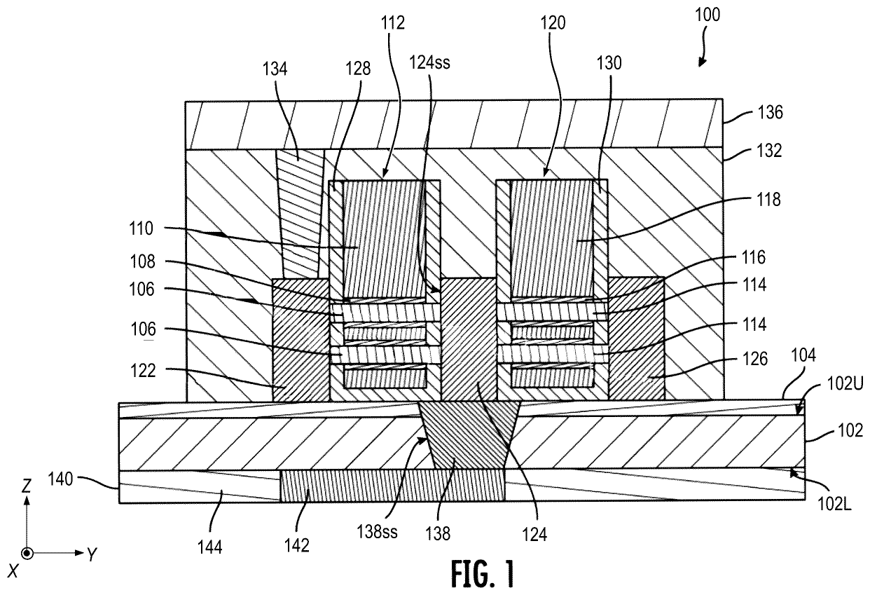

FIG. 1 is a schematic cross-sectional view of a first integrated circuit device 100 according to some embodiments. The first integrated circuit device 100 may include a first transistor and a second transistor on a substrate 102 that includes an upper surface 102U and a lower surface 102L. In some embodiments, the upper surface 102U of the substrate 102 may extend in a first direction X (which may be a first horizontal direction) and a second direction Y (which may be a second horizontal direction). The upper surface 102U of the substrate 102 may be parallel to the lower surface 102L of the substrate 102. Accordingly, the first direction X and the second direction Y may be parallel to the upper surface 102U and the lower surface 102L of the substrate 102. In some embodiments, the first direction X may intersect (e.g., be perpendicular to) the second direction Y.

The substrate 102 may include one or more semiconductor material(s), for example, silicon (Si), germanium (Ge), silicon germanium (SiGe), gallium phosphide (GaP), gallium arsenide (GaAs), silicon carbide (SiC), silicon germanium carbide (SiGeC) and/or indium phosphide (InP), or may include insulating material(s), for example, silicon oxide, silicon oxynitride, silicon nitride, silicon carbonitride and/or a low dielectric constant (low-k) material, although embodiments are not limited thereto. In some embodiments, the substrate 102 may be a bulk substrate (e.g., a bulk silicon substrate) or a semiconductor-on-insulator (SOI) substrate. For example, the substrate 102 may be a silicon wafer or may be a single insulating layer. A thickness of the substrate 102 in a third direction Z (which may be a vertical direction) may be in a range of about 50 nanometers (nm) to 100 nm. In some embodiments, the third direction Z may be perpendicular to the upper surface 102U and the lower surface 102L of the substrate 102 and may be perpendicular to the first direction X and second direction Y. For example, the low-k material may include fluorine-doped silicon oxide, organosilicate glass, carbon-doped oxide, porous silicon dioxide, porous organosilicate glass, spin-on organic polymeric dielectrics and/or spin-on silicon based polymeric dielectric.

The first integrated circuit device 100 may further include a first interlayer 104 that may be provided on the upper surface 102U of the substrate 102. In some embodiments, the first interlayer 104 may extend between the substrate 102 and the first and second transistors and may contact the upper surface 102U of the substrate 102 and the first and second transistors. For example, the first interlayer 104 may include insulating material(s) (e.g., silicon oxide, silicon oxynitride, silicon nitride, silicon carbonitride and/or a low-k material). The term “contact” (or “contacting,” or like terms, such as “connect” or “connecting”), as may be used herein, is intended to refer to a physical and/or electrical connection between two or more elements, and may include other intervening elements. As used herein, the term “and/or” includes any and all combinations of one or more of the associated listed items.

The first transistor may include a first channel region 106. In some embodiments, the first transistor may include multiple first channel regions 106 stacked in the third direction Z, and the first channel regions 106 may be spaced apart from each other in the third direction Z, as illustrated in FIG. 1. The first transistor may also include a first gate structure that may include a first gate insulator 108 and a first gate electrode 110. The first channel region 106 may extend through the first gate electrode 110 in the second direction Y, and the first gate insulator 108 may be provided between the first gate electrode 110 and the first channel region 106. The first gate insulator 108 may contact the first gate electrode 110 and the first channel region 106. Configured in this manner, a first channel structure of the first transistor (including the first channel regions 106, first gate insulators 108, and first gate electrodes 110) is formed as a first nano-sheet 112.

Similarly, the second transistor may include a second channel region 114. In some embodiments, the second transistor may include multiple second channel regions 114 stacked in the third direction Z, and the second channel regions 114 may be spaced apart from each other in the third direction Z, as illustrated in FIG. 1. The second transistor may also include a second gate structure that may include a second gate insulator 116 and a second gate electrode 118. The second channel region 114 may extend through the second gate electrode 118 in the second direction Y, and the second gate insulator 116 may be provided between the second gate electrode 118 and the second channel region 114. The second gate insulator 116 may contact the second gate electrode 118 and the second channel region 114. Configured in this manner, a second channel structure of the second transistor (including the second channel regions 114, second gate insulators 116, and second gate electrodes 118) is formed as a second nano-sheet 120.

Further, the first transistor may include first and second source/drain regions 122 and 124 that may be spaced apart from each other in the second direction Y, and the first gate structure may be provided between the first and second source/drain regions 122 and 124. The first and second source/drain regions 122 and 124 may contact opposing side surfaces of the first channel region 106, respectively, as illustrated in FIG. 1. The second transistor may include the second source/drain region 124 and a third source/drain region 126 that may be spaced apart from each other in the second direction Y, and the second gate structure may be provided between the second and third source/drain regions 124 and 126. The second and third source/drain regions 124 and 126 may contact opposing side surfaces of the second channel region 114, respectively, as illustrated in FIG. 1. The second source/drain region 124 may also be referred to as a common source/drain region, as the second source/drain region 124 is shared by the first and second transistors. The symbol “/” (e.g., when used in the term “source/drain”) will be understood to be equivalent to the term “and/or.”

Each of the first and second channel regions 106 and 114 may include semiconductor material(s) (e.g., Si, Ge, SiGe, GaP, GaAs, SiC, SiGeC and/or InP). In some embodiments, the first and second channel regions 106 and 114 may include the same material(s). In some embodiments, each of the first and second channel regions 106 and 114 may be a nano-sheet having a thickness in a range of from about 1 nm to 100 nm in the third direction Z or may be a nano-wire that may have a circular cross-section with a diameter in a range of from about 1 nm to 100 nm.

Each of the first and second gate insulators 108 and 116 may include a single layer or multiple layers (e.g., a silicon oxide layer and/or a high dielectric constant (high-k) material layer). For example, the high-k material layer may include aluminum oxide (Al₂O₃), hafnium oxide (HfO₂), zirconium oxide (ZrO₂), hafnium zirconium oxide (HfZrO₄), titanium oxide (TiO₂), scandium oxide (Sc₂O₃), yttrium oxide (Y₂O₃), lanthanum (III) oxide (La₂O₃), lutetium (III) oxide (Lu₂O₃), niobium pentoxide (Nb₂O₅) and/or tantalum oxide (Ta₂O₅), although embodiments are not limited thereto. In some embodiments, each of the first and second gate insulators 108 and 116 may include the same material(s).

Each of the first and second gate electrodes 110 and 118 may include a single layer or multiple layers. In some embodiments, each of the first and second gate electrodes 110 and 118 may comprise a metallic layer that includes, for example, tungsten (W), aluminum (Al), copper (Cu), molybdenum (Mo) and/or ruthenium (Ru), and may additionally include work function layer(s) (e.g., a titanium nitride (TiN) layer, a tantalum nitride (TaN) layer, a titanium aluminide (TiAl) layer, a titanium carbide (TiC) layer, a titanium aluminum carbide (TiAlC) layer, a titanium aluminum nitride (TiAlN) layer and/or a tungsten nitride (WN) layer), although embodiments are not limited thereto. In some embodiments, the first and second gate electrodes 110 and 118 may include the same material(s). The work function layer(s) may be provided between the metallic layer and the gate insulator (i.e., one of the first and second gate insulators 108 and 116). In some embodiments, the work function layer(s) may separate the metallic layer from the gate insulator.

Each of the first, second and third source/drain regions 122, 124 and 126 may include a semiconductor layer (e.g., a silicon layer and/or a silicon germanium layer) and may additionally include dopants in the semiconductor layer. In some embodiments, each of the first, second and third source/drain regions 122, 124 and 126 may include a metal layer that includes, for example, W, Al, Cu, Mo and/or Ru.

The first and second transistors may also respectively include first and second insulating spacers 128 and 130 (also referred to as a gate spacer or an inner gate spacer). The first insulating spacer 128 may be provided between the first gate electrode 110 and the respective first and second source/drain regions 122 and 124 and/or may be provided between the first gate electrode 110 and the first interlayer 104. In some embodiments, opposing surfaces of the first insulating spacer 128 may respectively contact the first gate electrode 110 and one of the first and second source/drain regions 122 and 124 and may respectively contact the first gate electrode 110 and the first interlayer 104, as illustrated in FIG. 1. The first channel region 106 may extend through the first insulating spacer 128 in the second direction Y, as illustrated in FIG. 1.

The second insulating spacer 130 may be provided between the second gate electrode 118 and the respective second and third source/drain regions 124 and 126 and/or may be provided between the second gate electrode 118 and the first interlayer 104. In some embodiments, opposing surfaces of the second insulating spacer 130 may respectively contact the second gate electrode 118 and one of the second and third source/drain regions 124 and 126 and may respectively contact the second gate electrode 118 and the first interlayer 104, as illustrated in FIG. 1. The second channel region 114 may extend through the second insulating spacer 130 in the second direction Y, as illustrated in FIG. 1. Each of the first and second insulating spacers 128 and 130 may include, for example, silicon oxide, silicon oxynitride, silicon nitride, silicon carbonitride and/or a low-k material, although embodiments are not limited thereto.

A second interlayer 132 may be provided on the first interlayer 104, and the first and second transistors may be provided in the second interlayer 132. Although FIG. 1 illustrates the second interlayer 132 as a single layer, in some embodiments, the second interlayer 132 may include multiple layers.

A source/drain contact 134 may be provided in the second interlayer 132 on the first source/drain region 122. The source/drain contact 134 may contact an upper surface of the first source/drain region 122 and extend in the third direction Z through the second interlayer 132. An upper surface of the source/drain contact 134 may be coplanar with an upper surface of the second interlayer 132; that is, the upper surface of the source/drain contact 134 may be at a same level, in the third direction Z, as the upper surface of the second interlayer 132, relative to the upper surface 102U of the substrate 102. The source/drain contact 134 may electrically connect the first source/drain region 122 to a conductive element (e.g., a conductive wire or a conductive via plug) of a BEOL structure 136 that is formed through the BEOL portion of device fabrication. As used herein, “a lower surface” refers to a surface facing the substrate 102, and “an upper surface” refers to a surface opposite the lower surface. Further, as used herein, “a lower portion” refers to a portion that is closer than “an upper portion” to the substrate 102 in the third direction Z and thus is between the upper portion and the substrate 102.

The BEOL structure 136 may include a BEOL insulating layer, conductive wires (e.g., metal wires) that are provided in the BEOL insulating layer and are stacked in the third direction Z, and conductive via plugs (e.g., metal via plugs), each of which may electrically connect two conductive wires that are spaced apart from each other in the third direction Z.

Each of the first and second interlayers 104 and 132 and the BEOL insulating layer may include, for example, silicon oxide, silicon oxynitride, silicon nitride, silicon carbonitride and/or a low-k material.

The first integrated circuit device 100 may further include a power contact 138 and a BSPDN structure 140. The power contact 138 may include an upper portion in the first interlayer 104 and a lower portion in the substrate 102. In some embodiments, the power contact 138 may extend through the first interlayer 104 and the substrate 102 in the third direction Z, and the power contact 138 (e.g., an upper surface of the power contact 138) may contact the second source/drain region 124 (e.g., a lower surface of the second source/drain region 124), as illustrated in FIG. 1. Further, the power contact 138 (e.g., the upper surface of the power contact 138) may contact at least a portion of the first and second insulating spacers 128 and 130, as illustrated in FIG. 1. In some embodiments, the power contact 138 may contact only one of the first and second insulating spacers 128 and 130; that is, a center line of the power contact 138 may be offset in the second direction Y from a center line of the second source/drain region 124.

The power contact 138 may include a first portion that the first channel region 106 overlaps in the third direction Z and a second portion that the second channel region 114 overlaps in the third direction Z. In some embodiments, the power contact 138 may include only one of the first and second portions. Further, each of the first and second gate electrodes 110 and 118 may overlap a portion of the power contact 138 in the third direction Z. As used herein, “an element A overlapping an element B in a direction X” (or similar language) means that there is at least one line that extends in the direction X and intersects both the elements A and B.

The upper surface of the power contact 138 may have a width in the second direction Y which is greater than a width of the lower surface of the second source/drain region 124 in the second direction Y. A side surface 138ss of the power contact 138 may protrude (i.e., extend) in the second direction Y beyond a side surface 124ss of the second source/drain region 124.

In some embodiments, a width of the power contact 138 in the second direction Y may decrease with increasing distance from the second source/drain region 124 in the third direction Z, and thus one or both opposing side surfaces 138ss of the power contact 138 may be inwardly sloped, as illustrated in FIG. 1. In some embodiments, a width of the power contact 138 in the first direction X may also decrease with increasing distance from the second source/drain region 124 in the third direction Z.

The power contact 138 may electrically connect the second source/drain region 124 to a conductive element (e.g., a conductive wire or a conductive via plug) of the BSPDN structure 140. The BSPDN structure 140 may include, for example, a power rail 142 and a backside insulator 144 in which the power rail 142 is provided. The power rail 142 may be electrically connected to a power source with a predetermined voltage (e.g., a drain voltage or a source voltage), and thus the second source/drain region 124 may be electrically connected to the power source through the power contact 138 and the power rail 142. In some embodiments, the power contact 138 may contact both the second source/drain region 124 and the power rail 142. Although the backside insulator 144 is illustrated as a single layer, in some embodiments, the backside insulator 144 may include multiple layers stacked on the lower surface 102L of the substrate 102. Further, although the BSPDN structure 140 is illustrated as contacting the lower surface 102L of the substrate 102, in some embodiments, an intervening structure may be provided between the substrate 102 and the BSPDN structure 140 and may separate the substrate 102 from the BSPDN structure 140. Each of the power contact 138 and the power rail 142 may include, for example, metal element(s) (e.g., W, Al, Cu, Mo and/or Ru), and the backside insulator 144 may include, for example, silicon oxide, silicon oxynitride, silicon nitride, silicon carbonitride and/or a low-k material, although embodiments are not limited thereto.

Traditionally, an IC device including a BSPDN structure and a nano-sheet may include an SASI layer (e.g., a bottom dielectric isolation (BDI), such as first interlayer 104, between the substrate 102 and a nano-sheet 112, 120) under the nano-sheet to protect the nano-sheet and increase the process margin of a placeholder (e.g., a sacrificial layer) for forming a BSCA, such as a backside power contact. Using an SASI scheme, a height of the SASI layer is an important parameter, and since SASI layer height is a function of placeholder height, placeholder height variation should be tightly controlled. However, placeholder height may be difficult to control due to process variations such as, for example, trench space etch, reactive ion etching (RIE) depth, and epitaxial growth, among other factors. Moreover, it is much more difficult to control SASI layer height for narrow pitch processes (e.g., less than 48 nm pitch) due at least in part to narrow trench spacing and hard mask thickness requirements.

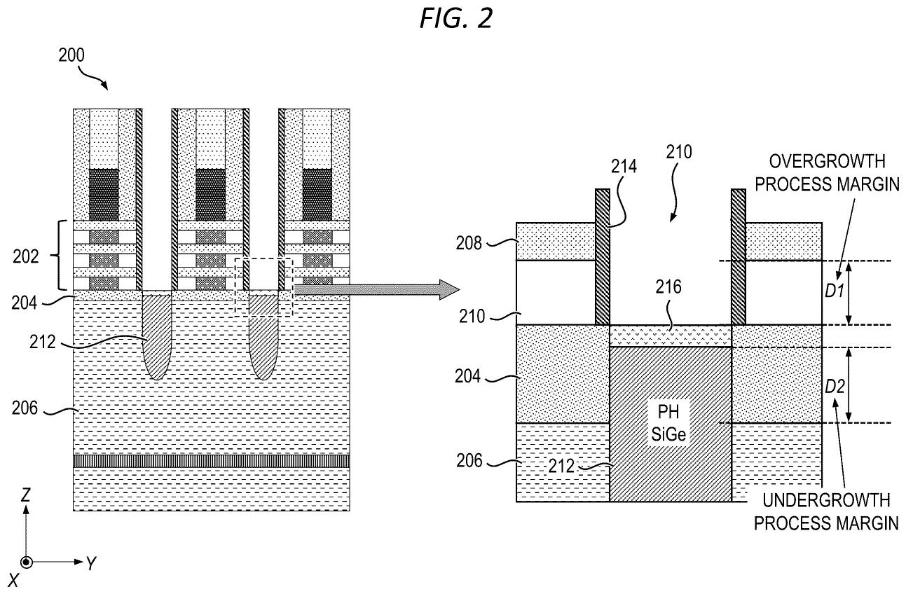

FIG. 2 is a schematic cross-sectional view conceptually depicting effects of placeholder height variation on nano-sheets in forming a metal-oxide-semiconductor (MOS) device. Referring to FIG. 2, which depicts an intermediate fabrication step, an MOS device 200 includes a plurality of transistors, each transistor comprising a nano-sheet stack 202. A bottom dielectric isolation (BDI) layer 204 may be disposed between a substrate 206 and the nano-sheet stack 202 in a third direction Z, perpendicular to a surface (upper or lower surface) of the substrate 206. The BDI layer 204, which may be referred to as a self-aligned substrate isolation (SASI) layer, is typically used under the nano-sheet stack 202 to protect the nano-sheet stack 202 and increase process margin.

As previously described with reference to FIG. 1, each nano-sheet stack 202 may include a plurality of channel layers 208 spaced apart from one another in the third direction Z by inner spacers 210; that is, each inner spacer 210 may be disposed between an adjacent pair of channel layers 208 in the third direction Z. Furthermore, the inner spacers 210 function to separate the gates from the source/drain regions. The inner spacers 210 may be formed of an insulating material, such as, for example, silicon oxide and/or a high-k material layer, although embodiments are not limited thereto. Each of the inner spacers 210 may include a single layer or multiple layers.

A trench (i.e., opening) 210 may be formed in the MOS device 200. The trench 210 may extend in the third direction Z through the nano-sheet stack 202 and may extend at least partially into the substrate 206 to expose a placeholder (PH) 212 formed in the substrate 206. The term “expose” (or “exposed,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. The placeholder 212, which may comprise, for example, silicon germanium (SiGe), may be a preformed placeholder disposed at least partially in the substrate 206 between adjacent nano-sheet stacks 202 in a first horizontal direction (i.e., X direction) parallel to the surface of the substrate 206 and may extend in a second horizontal direction (i.e., Y direction) parallel to the surface of the substrate 206 and intersecting the first horizontal direction.

A sidewall insulating layer 214 may be provided on at least sidewalls of the trench 210. The sidewall insulating layer 214 may protect the nano-sheet stack 202 during subsequent processing of the MOS device 200. The sidewall insulating layer 214 may comprise a dielectric material, such as, for example, silicon oxide, although embodiments are not limited thereto. A blocking layer (e.g., hard mask layer) 216 may be provided at a bottom of the trench 210 covering an upper surface of the placeholder 212. The term “covering” (or “covers,” or like terms), as may be used herein, is intended to broadly refer to an element, structure or layer that is on or over another element, structure or layer, either directly or with one or more other intervening elements, structures or layers therebetween. The blocking layer 216 may comprise, for example, silicon, and may therefore be referred to herein as a silicon pattern. The blocking layer 216 may serve as a barrier layer for the placeholder 212.

A height of an upper surface of the placeholder 212, relative to a surface of the substrate 206, combined with a thickness of the blocking layer 216 in the third direction Z, is an important parameter in the formation of a source/drain region of the MOS device 200. The source/drain region is formed to fill the trench 210 in a subsequent process step (e.g., epitaxial growth process). The term “fill” (or “fills,” or like terms) is intended to refer to either completely filling a defined space (e.g., trench 210) or partially filling the defined space; that is, the defined space need not be entirely filled but may, for example, be partially filled or have voids or other spaces throughout.

In one or more embodiments, a thickness in the third direction Z of the blocking layer 216 may be about 4 nanometers (nm). An overgrowth process margin may be defined by a distance D1 above a target level of an upper surface of the blocking layer 216, combined with a thickness of the blocking layer 216, in the third direction Z. The distance D1 may be defined such that the upper surface of the blocking layer 216 is at or below a level of a bottom surface of a lowermost one of the channel layers 208 in the nano-sheet stack 202 (see FIG. 2), relative to a surface of the substrate 206. The overgrowth process margin represents an upper bound on a level, in the third direction Z, of a bottom surface of the source/drain region formed in the trench 210, relative to a surface of the substrate 206. An undergrowth process margin may be defined by a distance D2 below the target level of the upper surface of the placeholder 212 in the third direction Z. The distance D2 may be defined such that the upper surface of the blocking layer 216 is at or above a level of a bottom surface of the BDI layer 204, relative to a surface of the substrate 206. The undergrowth process margin represents a lower bound on the level, in the third direction Z, of the bottom surface of the source/drain region formed in the trench 210, relative to the surface of the substrate 206. When the overgrowth process margin or the undergrowth process margin is exceeded, damage to the source/drain region of the MOS device 200 may occur.

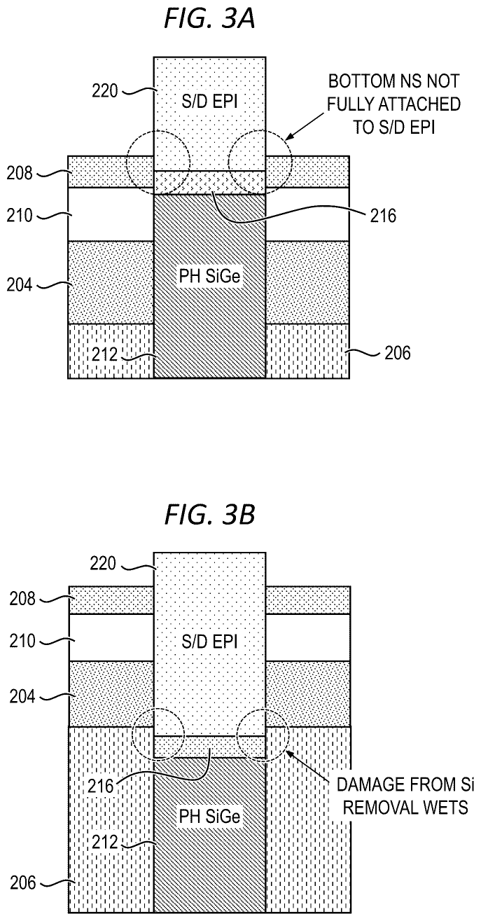

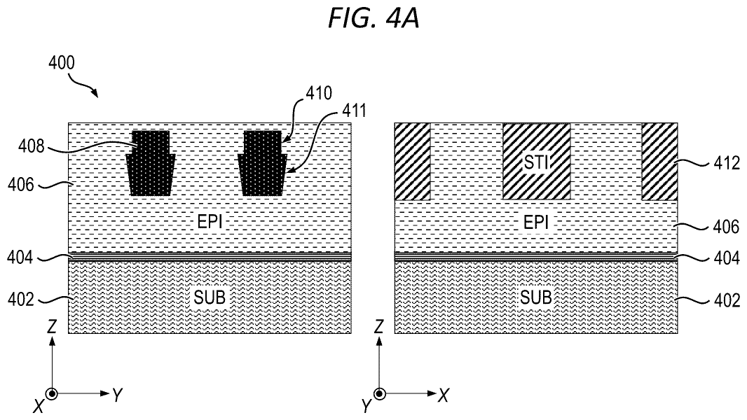

By way of example only and without limitation, FIGS. 3A and 3B are schematic cross-sectional views conceptually depicting damage to the source/drain region of the MOS device 200 that may occur when the overgrowth process margin or the undergrowth process margin, respectively, is exceeded. Referring to FIG. 3A, which depicts an overgrowth condition, the upper surface of the blocking layer 216 exceeds a level defined by the distance D1 (see FIG. 2) above the surface of the substrate 206. In this scenario, the placeholder 212 may block the nano-sheet stack 202, such that a lowermost one of the channel layers 208 in the nano-sheet stack 202 (see FIG. 2) does not fully contact a source/drain epitaxial region 220 of the MOS device 200. Referring to FIG. 3B, which depicts an undergrowth condition, the upper surface of the placeholder 212 is below a level defined by the distance D2 (see FIG. 2) above the surface of the substrate 206. In this scenario, damage to the source/drain epitaxial region 220 may occur due to removal of the silicon blocking layer 216 during backside processing.

According to methods described herein, the placeholder may be formed before performing processes (e.g., front-side device processes) of elements (e.g., the nano-sheet stack) on a front-side of a device, and the placeholder may be replaced with a conductor (e.g., a backside contact (BSCA), such as a backside power contact) after performing the front-side device processes. Accordingly, complexity and difficulties associated with the placeholder during front-side device processing may be avoided.

The placeholder (e.g., preformed placeholder) described herein may be formed below a source/drain (S/D) region such that an integrated circuit device may include a self-aligned direct backside contact (SADBC) scheme, and the conductor (e.g., the BSCA) formed by replacing the placeholder therewith may be connected to the S/D region. The preformed placeholder is formed prior to the transistor fabrication processes (e.g., nano-sheet stacks or source/drain regions).

In one or more embodiments, as will be described in further detail herein, the preformed placeholder may include at least two portions having different shapes (e.g., a shallow trench and a cavity) when depicted in a cross-sectional view. For example, a first portion of the preformed placeholder (e.g., the shallow trench) may have a rectangular shape in the cross-sectional view, and a second portion of the preformed placeholder (e.g., the cavity) may have an inverted trapezoidal shape in the cross-sectional view. The preformed placeholder may have different widths in a horizontal direction (i.e., in a plane parallel to a surface of the substrate). For example, the second (e.g., cavity) portion may have a width greater than a width of the first (e.g., shallow trench) portion in the horizontal direction so that the BSCA is more easily formed (aligned) to be connected to the source/drain region. In addition, a silicon blocking pattern, which may function as a barrier layer, may be provided on (e.g., overlapping in the third direction Z) the preformed placeholder so that tight control of the placeholder height is not necessary.

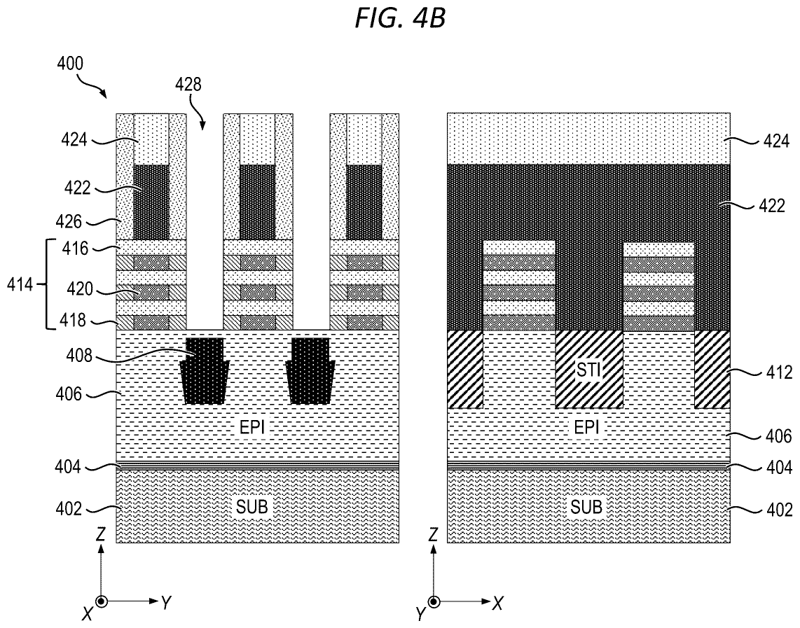

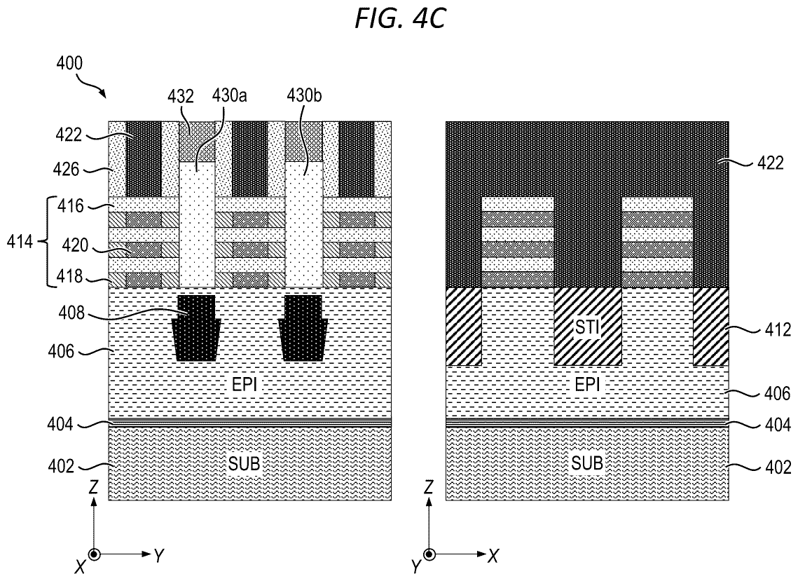

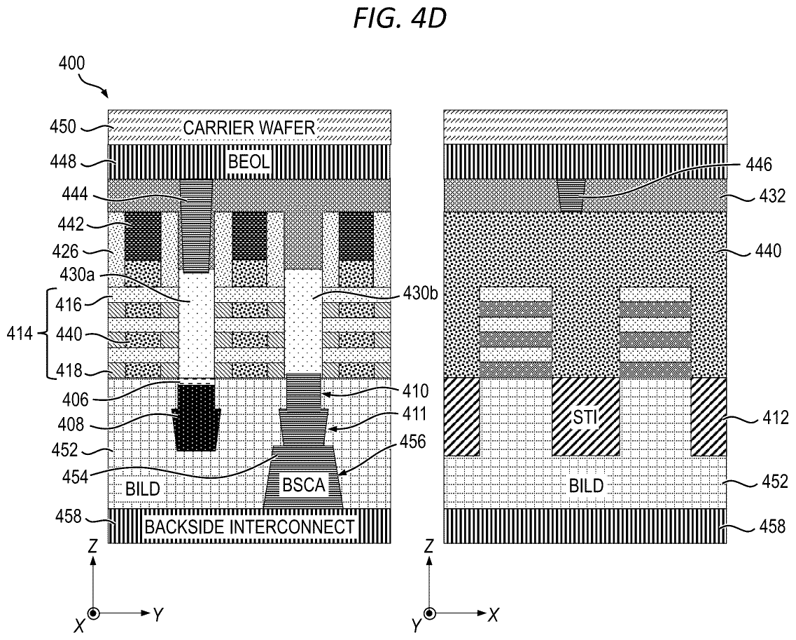

FIGS. 4A-4D are schematic cross-sectional views depicting intermediate processes in an example method of fabricating a semiconductor device, according to one or more embodiments of the inventive concept. Referring to FIG. 4A, a semiconductor device 400 is provided including a substrate 402, an etch stop layer 404 on the substrate 402, and an epitaxial layer 406 on the etch stop layer 404. The substrate 402 may comprise one or more semiconductor materials, such as, for example, Si, Ge, SiGe, GaP, GaAs, SiC, SiGeC and/or InP or may include an insulating material (e.g., silicon oxide, silicon oxynitride, silicon nitride, silicon carbonitride and/or a low-k material), although embodiments are not limited thereto. The etch stop layer 404 may comprise, for example SiGe. The epitaxial layer 406 may comprise one or more semiconductor material, for example, silicon. The epitaxial layer 406 may be doped with an impurity (e.g., boron, phosphorous, etc.) to change a conductivity type (e.g., n-type or p-type) of the epitaxial layer 406. A doping concentration of the epitaxial layer 406 may be different compared to a doping concentration of the substrate 402.

One or more preformed placeholders 408 (e.g., sacrificial layers) may be provided in the epitaxial layer 406, proximate an upper surface of the epitaxial layer 406. Each of the preformed placeholders 408 are formed prior to performing transistor processes (e.g., formation of a gate structure or source/drain regions). The preformed placeholders 408 may extend in a first direction X parallel to a surface (upper or lower surface) of the substrate 402 and may be spaced from one another in a second direction Y parallel to the surface of the substrate 402 and intersecting the first direction X. The preformed placeholders 408 may be disposed in the epitaxial layer 406 such that the epitaxial layer 406 covers an upper surface of the preformed placeholders 408.

Each of the preformed placeholders 408 may comprise at least two portions; a first portion 410 (e.g., shallow trench) having a substantially rectangular shape when viewed in a cross-sectional view, and a second portion 411 (e.g., a cavity) having a substantially inverted trapezoidal shape when view in the cross-sectional view. The first portion 410 of the preformed placeholder 408 is formed on the second portion 411. The first and second portions 410, 411 of the preformed placeholder 408 may be a homogeneous structure, such that a boundary between the first portion 410 and the second portion 411 may not be apparent.

The different portions 410, 411 of each of the preformed placeholders 408 may have different widths in the first direction X and/or the second direction Y relative to one another. For example, the second portion 411 may have a width in the second direction Y greater than a width of the first portion 410 in the second direction Y so that the BSCA (subsequently formed from the preformed placeholder 408) is more easily formed (aligned) for connection to a source/drain region of the semiconductor device 400. The second portion 411 of the preformed placeholder 408 may have a width in the second direction Y that decreases as the second portion 411 extends in a third direction Z, perpendicular to the surface of the substrate 402, towards the substrate 402. It is to be appreciated that the specific shape and/or dimensions of the preformed placeholder 408 is not limited to the illustrative embodiment shown.

The preformed placeholder 408 may comprise, for example, a semiconductor material and/or an insulating material (e.g., SiGe, SiN or SiBCN). The material forming the preformed placeholder 408 may be different than materials forming other elements and/or structures in the semiconductor device 400 to allow selective etching/removal. In some embodiments, the preformed placeholder 408 may include a SiGe layer including about 25 atomic percent (at %) of germanium (e.g., from 15 at % to 25 at %). When a source/drain region in the semiconductor device 400 includes a SiGe layer, a germanium concentration of the source/drain region may be higher than the germanium concentration of the SiGe layer of the preformed placeholder 408. For example, the germanium concentration of the source/drain region may be about 55 at % (e.g., from 40 at % to 70 at %).

A plurality of isolation structures 412, which may shallow trench isolation (STI) structures may be provided in the epitaxial layer 406, proximate the upper surface of the epitaxial layer 406. In one or more embodiments, an upper surface of the isolation structures 412 may be coplanar with an upper surface of the epitaxial layer 406. The isolation structures 412 may extend in the second direction Y and may be spaced from one another in the first direction X. The isolation structures 412 may define active regions in the epitaxial layer 406 between adjacent isolation structures 412.

Referring to FIG. 4B, the semiconductor device 400 may include one or more nano-sheet stacks 414 formed on the upper surface of the epitaxial layer 406. Unlike the example embodiments shown in FIGS. 2, 3A and 3B, the BDI layer (204 in FIG. 2) disposed between the nano-sheet stacks 414 and the substrate 402 is omitted in the illustrative semiconductor device 400 such that the device 400 is free of the BDI layer between the nano-sheet stacks 414 and the substrate 402. The nano-sheet stacks 414 may be aligned with and overlap the epitaxial layer 406 in the third direction Z between isolation structures 412. As used herein, “an element A overlapping an element B in a direction X” (or similar language) means that there is at least one line that extends in the direction X and intersects both the elements A and B. The nano-sheet stacks 414 may extend in the second direction Y and may be spaced apart from one another in the first direction X.

Each of the nano-sheet stacks 414 may include a plurality of channel regions 416 spaced apart from one another in the third direction Z by inner spacers 418; that is, each inner spacer 418 may be disposed between an adjacent pair of channel regions 416 in the third direction Z. Each of the nano-sheet stacks 414 may further comprise a gate electrode 420. The channel regions 416 may extend in the second direction Y through the gate electrode 420, and a gate insulator (e.g., 108 in FIG. 1) may be provided between the gate electrode 420 and the respective channel regions 416. The gate insulator may contact the gate electrode 420 and the channel regions 416. As previously stated, the BDI layer (204 in FIG. 2) is omitted in this embodiment (non-SASI scheme), and therefore a bottom surface of the gate electrode 420 may directly contact the epitaxial layer 406.

The channel regions 416 may comprise a semiconductor material, such as, for example, silicon, although embodiments are not limited thereto. The inner spacers 418 may be formed of an insulating material, such as, for example, silicon oxide and/or a high-k material layer, although embodiments are not limited thereto. Each of the inner spacers 418 may include a single layer or multiple layers.

The semiconductor device 400 may further include a dummy gate 422 and a hard mask 424 disposed on the dummy gate 422. The dummy gate 422 may be disposed on the isolation structures 412. The dummy gate 422 may extend in the first direction X and may be spaced apart from one another in the second direction Y. The dummy gate 422 may overlap the gate electrode 420 in the third direction Z. The hard mask 424 may extend along an upper surface of the dummy gate 422. Sidewall spacers 426 may be provided on opposing sidewalls of the dummy gate 422 and hard mask 424 in the second direction Y. The dummy gate 422, hard mask 424 and sidewall spacers 426 may form a dummy gate structure.

One or more trenches (i.e., openings) 428 may be provided between adjacent dummy gate structures. The trenches 428 may extend in the third direction Z through the nano-sheet stacks 414 to expose at least a portion of an upper surface of the epitaxial layer 406 at a bottom of the trenches 428. Opposing sidewalls of the trenches 428 may expose the respective sidewall spacers 426 of adjacent dummy gate structures. The sidewalls of the trenches 428 may also expose sides of the channel regions 416 and inner spacers 418. The trenches 428 may be formed, for example, using an anisotropic etching process, such as reactive ion etching (RIE), wet etching, or the like, although embodiments are not limited thereto.

Referring to FIG. 4C, in one or more embodiments, sidewalls of the first portion (410 in FIG. 4A) of each of the preformed placeholders 408 may be aligned in the third direction Z with the sidewalls of the trenches 428 (see FIG. 4B). Source/drain regions 430a and 430b, collectively 430, may be formed on the epitaxial layer 406 and partially filling the trenches 428 (see FIG. 4B). Each of the source/drain regions 430a, 430b may extend upwardly from the epitaxial layer 406 in the third direction Z beyond the nano-sheet stacks 414, so that an upper surface of the source/drain regions 430 is at or above an upper surface of an uppermost one of the plurality of channel regions 416, relative to the surface of the substrate 402. Each of the source/drain regions 430a, 430b may be disposed between adjacent nano-sheet stacks 414 in the second direction Y. The source/drain regions 430 may be electrically isolated from the dummy gate 422 by the sidewall spacers 426. Sidewalls of the source/drain regions 430 may contact opposing side surfaces of the channel regions 416 and may be electrically isolated from the gate electrode 420 by the inner spacers 418 of the nano-sheet stacks 414.

In one or more embodiments, the source/drain regions 430 may be formed, for example, by an epitaxial growth process using the epitaxial layer 406 as a seed layer. The source/drain regions 430 may comprise, for example, silicon, although embodiments are not limited thereto. The source/drain regions 430 may be doped with an impurity of a prescribed doping concentration level to change a conductivity type of the source/drain regions 430 as desired. The conductivity type of each of the source/drain regions 430a, 430b may not necessarily be the same. For example, one of the source/drain regions 430a may be configured having an n-type conductivity and another of the source/drain regions 430b may be configured having a p-type conductivity. In this manner, the semiconductor device 400 may comprise p-type MOS (PMOS) transistors and n-type MOS (NMOS) transistors in a complementary MOS (CMOS) structure.

A first interlayer insulating layer 432 (e.g., interlayer dielectric (ILD) layer) may be provided on the semiconductor device 400, including on the source/drain regions 430 and extending on the hard mask layer 424 (see FIG. 4B) and on the spacers 426. A planarization process, such as, for example, chemical-mechanical polishing/planarization (CMP), grinding, or the like, may be performed to remove the hard mask layer 424 (see FIG. 4B) so that an upper surface of the first interlayer insulating layer 432 is coplanar with upper surfaces of the dummy gate 422 and spacers 426 in the third direction Z.

Referring to FIG. 4D, the dummy gate (422 in FIG. 4C) and gate electrode (420 in FIG. 4C) in the nano-sheet stacks 414 may be replaced with a second gate electrode 440. The second gate electrode 440 may be formed using, for example, a replacement gate process. The second gate electrode 440 may comprise a different material compared to the gate electrode 420 and dummy gate 422 (see FIG. 4C). A capping layer 442 may be provided on at least a portion of the second gate electrode 440. An upper surface of the capping layer 442 may be coplanar with a bottom surface of the first interlayer insulating layer 432 in the third direction Z.

A first contact 444 may be formed in the first interlayer insulating layer 432. The first contact 444 may overlap one of the source/drain regions 430a in the third direction Z and may extend in the third direction Z through the first interlayer insulating layer 432 to electrically contact the source/drain region 430a. In some embodiments, a width of the first contact 444 in the second direction Y may be less than a width of the source/drain region 430a in the second direction Y, so that sidewalls of the first contact 444 are in contact with the first interlayer insulating layer 432. The first contact 444 may extend in the third direction Z partially into the source/drain region 430a so that a bottom and a portion of the sidewalls of the first contact 444 may be in contact with the source/drain region 430a. An upper surface of the first contact 444 may be coplanar with the upper surface of the first interlayer insulating layer 432 in the third direction Z. The first contact 444 may comprise a conductive material, such as, for example, a metal.

A second contact 446 may be formed in the first interlayer insulating layer 432. The second contact 446 may extend through the first interlayer insulating layer 432 in the third direction Z to electrically contact the second gate electrode 440. An upper surface of the second contact 446 may be coplanar with the upper surface of the first interlayer insulating layer 432 in the third direction Z. The second contact 446 may comprise a conductive material, such as, for example, a metal.

A first BEOL layer 448, which may comprise a frontside interconnect structure, may be provided on the first interlayer insulating layer 432, the first contact 444 and the second contact 446. In one or more embodiments, the first BEOL layer 448 may include one or more metal interconnect layers and/or conductive vias patterned to electrically connect individual elements (e.g., transistors, resistors, capacitors, etc.), that may be formed during FEOL processing, to one another. The first BEOL layer 448 may also provide a source of power and/or ground to the semiconductor device 400. A carrier wafer 450, or alternative substrate, may be provided on the first BEOL layer 448. The carrier wafer 450 may be used as a temporary support structure for performing subsequent backside processing of the semiconductor device 400.

During backside processing, the substrate 402 may be removed, such as, for example by CMP processing or the like, to expose the etch stop layer 404. The semiconductor device 400 may be flipped upside down during backside processing such that the semiconductor device 400 is supported on the carrier wafer 450. The etch stop layer 404 and the epitaxial layer 406 may be removed such as, for example, by selective etching, leaving the preformed placeholders 408 and the isolation structures 412 remaining. In this manner, only a portion of the epitaxial layer 406 disposed between the preformed placeholders 408 and the source/drain regions 430 will remain. This remaining epitaxial layer 406 may serve as a barrier layer or blocking layer of the completed MOS transistor(s).

A second interlayer insulating layer 452, which may be a backside interlayer dielectric (BILD) layer, may be formed on a backside of the semiconductor device 400, including on a bottom surface of the nano-sheet stacks 414 and surrounding the preformed placeholders 408. The term “surrounding” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles.

At least a first one of the preformed placeholders 408 may be removed (e.g., by an etching process selective to the material forming the preformed placeholder 408). After removal of the first one of the preformed placeholders 408, the surrounding second interlayer insulating layer 452, which is not etched, will remain thereby forming a cavity having a profile (i.e., boundary shape) of the original preformed placeholder 408. An opening may be formed through at least a portion of the epitaxial layer 406 between the first one of the preformed placeholders 408 and the source/drain region 430b overlapping the first one of the preformed placeholders 408 to expose the source/drain region 430b therein. The opening may extend partially into the source/drain region 430b. The cavity remaining after removal of the first one of the preformed placeholders 408 may be filled with a conductive material (e.g., metal) to form a backside contact (BSCA) 454.

The backside contact 454 may extend in the third direction Z through the second interlayer insulating layer 452 to electrically connect to the source/drain region 430b. In one or more embodiments, a width in the second direction Y of a portion of the backside contact 454 partially extending in the third direction Z into the source/drain region 430b may be less than a width in the second direction Y of the source/drain region 430b. A vertical centerline of the backside contact 454 may be aligned in the third direction Z with a vertical centerline of the source/drain region 430b.

In one or more embodiments, the backside contact 454 will have a shape substantially matching the shape of the preformed placeholder 408, including the first portion 410 and the second portion 411. As previously described in connection with FIG. 4A, the first portion 410 may be substantially rectangular in shape and the second portion 411 may be shaped substantially as an inverted trapezoid, although embodiments are not limited thereto. The backside contact 454 may further comprise a third portion 456 in contact with the second portion 411; that is, the second portion 411 may be disposed on the third portion 456. The third portion 456 of the backside contact 454 may be trapezoidal in shape, although embodiments are not limited thereto. A width in the second direction Y of the third portion 456 may be greater than the width in the second direction Y of the second portion 411. Furthermore, the width in the second direction Y of the third portion 456 may increase with increasing distance in the third direction Z away from the source/drain region 430b. The third portion 456 may extend in the third direction Z through the second interlayer insulating layer 452. The third portion 456 is electrically connected to the source/drain region 430b via the first and second portions 410, 411 of the backside contact 454.

A bottom surface of the third portion 456, opposite the source/drain region 430b, may be coplanar with the bottom surface of the second interlayer insulating layer 452 in the third direction Z. In one or more embodiments, the first portion 410, the second portion 411, and the third portion 456 of the backside contact 454 may be formed as a homogeneous structure whereby a boundary between the first and second portions 410, 411 and a boundary between the second and third portions 411, 456 may not be apparent. In other embodiments, the first, second and third portions 410, 411, 456 of the backside contact 454 may be formed of different materials.

A second BEOL layer 458, which may be a backside interconnect structure, may be provided on the bottom surface of the second interlayer insulating layer 452 and the bottom surface of the third portion 456 of the backside contact 454. In one or more embodiments, the second BEOL 458, like the first BEOL layer 448, may include one or more metal interconnect layers and/or conductive vias patterned to electrically connect individual elements (e.g., transistors, resistors, capacitors, etc.), that may be formed during FEOL processing, to one another. The second BEOL layer 458 may also provide a source of power and/or ground to the semiconductor device 400. The source/drain region 430b may be electrically connected to the second BEOL layer 458 via the backside contact 454.

In accordance with embodiments of the inventive concept described herein, in fabricating transistor devices including nano-sheets, preformed placeholders are provided prior to beginning transistor processes, such as formation of the nano-sheet stacks or the source/drain regions of the transistors. The preformed placeholders may be formed as a multi-shaped structure. For example, in one or more embodiments, the preformed placeholders may comprise at least two shapes; namely, a first portion (e.g., 410 in FIG. 4A) having a shallow trench shape (e.g., rectangular shape) and a second portion (e.g., 411 in FIG. 4A) having a cavity shape (e.g., trapezoidal shape). The second portion may be wider in a direction parallel to a substrate of the device than the first portion which is configured to provide easier alignment with and connection to a backside contact (e.g., BSCA) of the device.

The transistors according to embodiments of the inventive concept are formed without an SASI layer (i.e., non-SASI scheme). In one or more embodiments, the preformed placeholders may be covered by a silicon pattern which may serve as a barrier or blocking layer between the preformed placeholders and the source/drain regions of the transistor device. Configured in this manner, tight control of the height of the placeholder is unnecessary. In one or more embodiments, transistor features are maintained so that the gate patterns will be precisely aligned to the preformed placeholders. The transistor features that are maintained may include, but are not limited to, the shape and/or dimensions of one or more transistor elements (e.g., source/drain regions, nano-sheet stack, etc.), but may also include performance of the transistor as well, among other factors. For example, in one or more embodiments, the shape of the nano-sheet stack and/or the source/drain region connection are maintained, and leakage performance of the transistor is maintained.

Aspects of the present inventive concept can provide substantial beneficial technical effects. By way of example only and without limitation, techniques according to embodiments of the present disclosure may provide one or more of the following advantages, among other benefits:
complexity and difficulties associated with processes of forming a placeholder in an IC device during front-side device processing may be avoided;
front-side device processing may not be affected by processes of forming a placeholder;
an improved process margin (e.g., a smaller placeholder) may be achieved by removing an SASI layer (i.e., non-SASI scheme);
fine control of placeholder height under a nano-sheet may not be necessary since a silicon layer is disposed on the placeholder as a blocking layer;
a deep trench for a BSCA (e.g., a backside power contact) may be relatively easily formed (e.g., aligned with a source/drain region), as a deep trench is formed in the IC device by a preformed placeholder having at least two different shapes in a cross-sectional view.

Example embodiments are described herein with reference to the accompanying drawings. Many different forms and embodiments are possible without deviating from the teachings of the present disclosure and so this disclosure should not be construed as limited to the example embodiments set forth herein. Rather, these example embodiments are provided so that this disclosure will be thorough and complete, and will convey the scope of the present invention to those skilled in the art. In the drawings, the sizes and relative sizes of layers and regions may be exaggerated for clarity and therefore the layers and regions may not necessarily be drawn to scale.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” “in contact with,” “contacting,” “responsive” to, or “on” (or like terms), another element, it can be directly coupled, connected, contacting, responsive to, or on, the other element, or intervening elements may also be present. In contrast, when an element is referred to as being “directly coupled,” “directly connected,” “directly contacting,” or “directly responsive” to, or “directly on” (or like terms), another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

It will be understood that although ordinal terms such as “first,” “second,” etc., may be used herein to describe various elements, these elements should not be limited by such terms. These terms are used merely to distinguish one element from another and are not intended to convey any particular order, unless the context clearly indicates otherwise. Thus, a first element could be termed a second element, and vice versa, without departing from the teachings of the present embodiments.

Spatially relative terms, such as, but not limited to, “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over (i.e., upside down), elements described as “below” or “beneath” other elements or features would then be oriented “above” or “over” the other elements or features. Thus, the term “below” can encompass both an orientation of above and below. The device may be otherwise oriented (e.g., rotated 90 degrees or at other orientations) and the spatially relative descriptors used herein may be interpreted accordingly.

Many different embodiments have been disclosed herein, in connection with the above description and the drawings. It will be understood that it would be unduly repetitious and obfuscating to literally describe and illustrate every combination and sub-combination of these embodiments. Accordingly, the present specification, including the drawings, shall be construed to constitute a complete written description of all combinations and sub-combinations of the embodiments described herein, and of the manner and process of making and using them, and shall support claims to any such combination or sub-combination. The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope is to be determined by the broadest permissible interpretation of the following claims and their equivalents, and shall not be restricted or limited by the foregoing detailed description.

What is claimed is:

1. A method of forming an integrated circuit device, the method comprising:
forming a sacrificial element in an epitaxial layer, the sacrificial element including a first portion and a second portion contacting the first portion;
forming a transistor comprising a channel structure and a source/drain region on an upper surface of the epitaxial layer, wherein an upper surface of the second portion of the sacrificial element faces the source/drain region, and wherein a portion of the epitaxial layer is between the upper surface of the second portion and the source/drain region;
removing at least a portion of the epitaxial layer extending around the sacrificial element to expose a lower surface and sidewalls of the sacrificial element;
forming an interlayer insulating layer extending around the sacrificial element;
replacing the sacrificial element with a power contact, wherein the source/drain region contacts an upper surface of the power contact; and
forming a power rail on a lower surface of the interlayer insulating layer that contacts a lower surface of the power contact.

2. The method of claim 1, wherein the first portion of the sacrificial element is shaped as an inverted trapezoid and the second portion of the sacrificial element is rectangular in shape, and wherein an upper surface of the first portion contacting the second portion is configured having a width in a first direction parallel to the upper surface of the epitaxial layer that is greater than a width of the second portion in the first direction.

3. The method of claim 1, wherein the channel structure of the transistor comprises a nano-sheet stack, the nano-sheet stack comprising a plurality of channel regions extending in a first direction parallel to the upper surface of the epitaxial layer and being spaced apart from one another in a second direction, perpendicular to the upper surface of the epitaxial layer, by at least one inner spacer.

4. The method of claim 3, wherein the nano-sheet stack further comprises a gate electrode and a gate insulator, the plurality of channel regions extending through the gate electrode in the first direction, the gate insulator being formed between the gate electrode and the plurality of channel regions.

5. The method of claim 3, wherein the nano-sheet stack is formed directly on the epitaxial layer.

6. The method of claim 1, wherein the transistor is formed subsequent to forming the sacrificial element.

7. The method of claim 2, wherein the power contact comprises a first portion, a second portion on an upper surface of the first portion, and a third portion on a lower surface of the first portion, opposite the second portion, wherein each of the first and second portions of the power contact has a same shape as the first and second portions, respectively, of the sacrificial element, and wherein the third portion of the power contact has a trapezoidal shape, an upper surface of the third portion having a width in the first direction that is greater than a width of the lower surface of the second portion in the first direction.

8. The method of claim 1, wherein sidewalls of the source/drain region are aligned in a second direction, perpendicular to the upper surface of the epitaxial layer, with sidewalls of the second portion of the sacrificial element.

9. The method of claim 1, further comprising forming a back-end-of-line (BEOL) structure on the lower surface of the interlayer insulating layer, the BEOL structure comprising the power rail, the source/drain region electrically connected to the BEOL structure via the power contact.

10. The method of claim 1, wherein the power contact extends in a second direction perpendicular to the upper surface of the epitaxial layer, into the source/drain region, so that an upper surface of the power contact is above a lower surface of the source/drain region in the second direction, relative to the upper surface of the epitaxial layer.

11. The method of claim 3, wherein an interface between the source/drain region and the portion of the epitaxial layer that separates the source/drain region from the second portion of the sacrificial element is at or below a bottom surface of a lowermost one of the channel regions of the nano-sheet stack.

12. The method of claim 1, wherein the integrated circuit device is free of a bottom dielectric isolation (BDI) layer between the channel structure and the upper surface of the epitaxial layer.

13. An integrated circuit device, comprising:
an epitaxial layer;
a channel structure;
a source/drain region on an upper surface of the epitaxial layer and contacting the channel structure in a first direction parallel to the upper surface of the epitaxial layer;
a backside contact electrically connected to the source/drain region; and
a back-end-of-line (BEOL) structure on a lower surface of the epitaxial layer, opposite the upper surface of the epitaxial layer, the BEOL structure contacting the backside contact,
wherein the backside contact comprises a first portion and a second portion on the first portion and contacting the source/drain region, a width of the first portion in the first direction being greater than a width of the second portion in the first direction.

14. The integrated circuit device of claim 13, wherein the first portion of the backside contact is shaped as an inverted trapezoid and the second portion of the backside contact is rectangular in shape.

15. The integrated circuit device of claim 13, wherein the channel structure is directly on an upper surface of a backside interlayer insulating layer.

16. The integrated circuit device of claim 13, wherein the channel structure comprises a nano-sheet stack, the nano-sheet stack comprising a plurality of channel regions extending in the first direction and being spaced apart from one another in a second direction, perpendicular to the upper surface of the epitaxial layer, by at least one inner spacer.

17. The integrated circuit device of claim 16, wherein the nano-sheet stack further comprises a gate electrode and a gate insulator, the plurality of channel regions extending through the gate electrode in the first direction, the gate insulator is between the gate electrode and the plurality of channel regions.

18. The integrated circuit device of claim 13, wherein the BEOL structure comprises a power rail, the source/drain region is electrically connected to the power rail via the backside contact.

19. The integrated circuit device of claim 16, wherein an interface between the source/drain region and the upper surface of the epitaxial layer is at or below a bottom surface of a lowermost one of the channel regions of the nano-sheet stack.

20. The integrated circuit device of claim 13, wherein the integrated circuit device is free of a bottom dielectric isolation (BDI) layer between the channel structure and the upper surface of the epitaxial layer.
